(19) United States
(12) Patent Application Publication
(10) Pub. No.: US 2024/0244800 A1
(43) Pub. Date: Jul. 18, 2024

(54) HYBRID COOLER TO THERMALLY COOL SEMICONDUCTOR DEVICES INSIDE AND OUTSIDE A CHIP PACKAGE

(71) Applicant: Intel Corporation, Santa Clara, CA (US)

(72) Inventors: Prabhakar SUBRAHMANYAM, San Jose, CA (US); Pooya TADAYON, Portland, OR (US); Yi XIA, Campbell, CA (US); Ying-Feng PANG, San Jose, CA (US); Mark BIANCO, Mountain View, CA (US)

(21) Appl. No.: 18/290,288

(22) PCT Filed: Sep. 24, 2021
(86) PCT No.: PCT/US21/52028

§ 371 Date: Nov. 10, 2023

(51) Int. Cl. H05K 7/20

(52) U.S. Cl. CPC H05K 7/20809; H05K 7/20336; H05K 7/2039

(57) ABSTRACT

An apparatus is described. The apparatus includes a chip package cooling assembly chamber having one or more features to receive one or more heat pipes that receive heat generated by one or more semiconductor devices that reside outside the chip package. In detail, the heat pipes that are thermally coupled to the VR FET heat sinks are attached to the outside of the cold plate (again, they can be screwed to the cold plate with a thermal interface material between them). Thus, heat generated by the VR FETs is transferred to the VR FET heatsinks and the chip package cold plate via the heat pipes. The heat is then transferred to the fluid while it runs through the cold plate and is removed from the system by the fluid as it exits the outlet.

### BACKGROUND

System design engineers face challenges, especially with respect to high performance data center computing, as both computers and networks continue to pack higher and higher levels of performance into smaller and smaller packages. Creative packaging solutions are therefore being designed to keep pace with the thermal requirements of such aggressively designed systems.

### FIGURES

FIG. 1 (prior art);

FIG. 2 depicts a chip package heat sink that is thermally coupled to heat pipes;

FIG. 3 depicts a traditional liquid cooling chamber that is thermally coupled to heat pipes;

FIG. 4 depicts a first two phase immersion cooling chamber that is thermally coupled to heat pipes;

FIG. 5 depicts a second two phase immersion cooling chamber that is thermally coupled to heat pipes;

FIGS. 6a and 6b show heat pipes that can be rotationally engaged with a chamber;

FIG. 7 shows a first arrangement of heat pipes and a chamber;

FIG. 8 shows a second arrangement of heat pipes and a chamber;

FIGS. 9a, 9b and 9c show heat pipes integrated into the ceiling of a chamber;

FIG. 10 shows a liquid cooling apparatus;

FIG. 11 shows a system;

FIG. 12 shows a data center;

FIG. 13 shows a rack.

### DETAILED DESCRIPTION

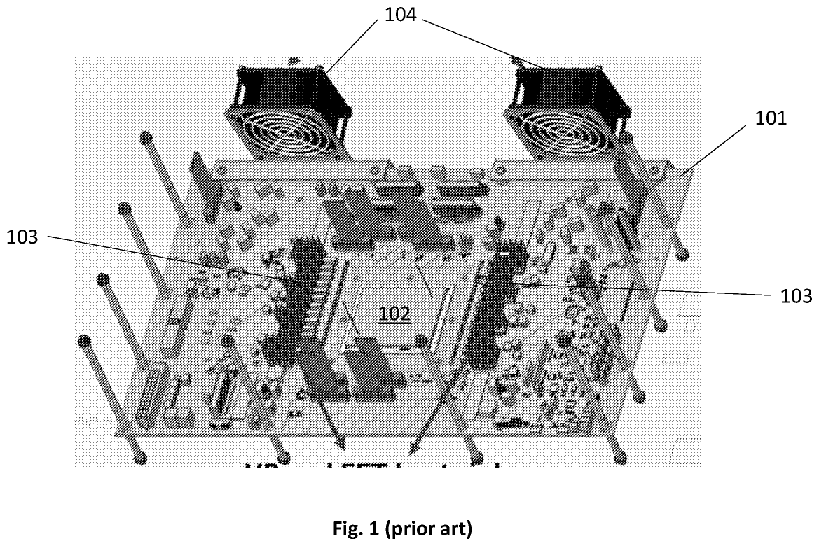

FIG. 1 shows the layout and mechanical design that is typical for many high performance electronic systems (e.g., computers, networking systems, etc.). As observed in FIG. 1, a package 102 containing one or more high performance semiconductor chips (e.g., general purpose processor, graphics processor, neural network processor, network processor, networking switch application specific integrated circuit (ASIC)) is disposed on a printed circuit board 101 along with other semiconductor chips (e.g., memory chips, networking interface chips, voltage regulators) and components (e.g., capacitors, resistors, power transistors (e.g., power field effect transistors (FETs), etc.).

The mechanical design also includes a number of cooling related components. These include, a heat sink (not shown) that resides on the package 102 of the high performance semiconductor chip(s) (hereinafter, “chip package”) and heatsinks 103 on the voltage regulator field effect transistors (VR FETs). Heat that is generated by the high performance semiconductor chip(s) is transferred to the heat sink that sits atop chip package 102. Likewise, heat generated by the VR FETs is transferred to the FETs' respective heat sinks 103. The fans 104 blow cool air over the printed board 101. Ideally, the cool air blows through each of the heat sinks to remove the heat that they radiate.

Unfortunately, because the VR FET heat sinks 103 have a low profile, the passage ways between them and the fans 104 are easily obstructed (at least partially). As such, the VR FET heat sinks 103 often receive air flow that is marginally sufficient which, in turn, raises the temperature of the overall ambient above the printed circuit board 101 (including the space in and around the chip package's heat sink).

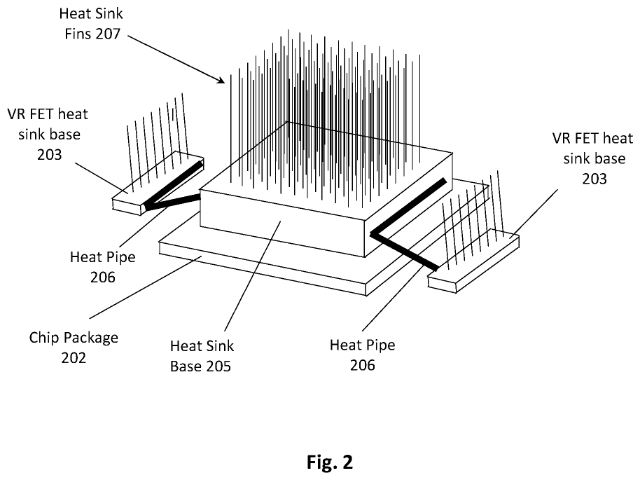

A solution, as observed in FIG. 2, is to thermally couple the VR FET heat sinks 203 to the base 205 of the chip package heat sink. Here, as observed in FIG. 2, a respective heat pipe 206 exists between each VR FET heat sink 203 and the base 205 of the chip package heat sink. A heat pipe is a thermally conductive material, such as a metal (e.g., copper), used to transfer heat from one component to another component. In this case, the respective heat pipe 206 that couples the heat sink of a particular VR FET to the base 205 of the chip package heat sink transfers heat generated by the VR FETs that reside beneath the VR FET heat sinks 203 to the chip package heat sink.

The chip package heat sink 205, 207 has greater surface area than the VR FET heat sinks 203 and is positioned mostly if not entirely without obstruction between itself and the cooling fans. As such, the chip package heat sink 205, 207 has much greater capacity to absorb and radiate heat than the VR FET heat sinks 203. Thus, the chip package heat sink 205, 207 “helps out” the VR FET heat sinks 203 when they are thermally coupled to the semiconductor chip package heat sink 205, 207.

As observed in the particular embodiment of FIG. 2, the heat pipes 206 are coupled to the sides of the base 205 of the chip package heat sink. Here, the heat pipes 206 can be screwed into the sides of the heat sink base 205 with thermal interface materials between them.

Although the approach of FIG. 2 can improve present day systems that use traditional air cooled heat sinks 205, 207 on the chip package 202, the heat dissipation of high performance semiconductor chips continues to grow to the point where traditional air cooling is rapidly becoming obsolete. Instead, liquid cooling is being designed into leading edge designs.

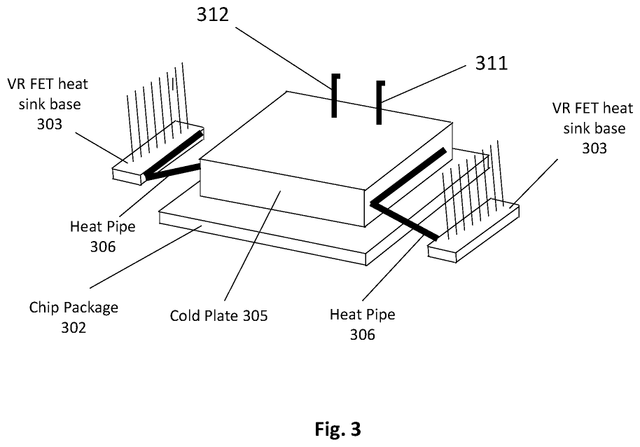

As such, FIG. 3 shows a similar approach but where the traditional air cooled heat sink is replaced with a cold plate 305 and associated fluidic channels. A traditional heat sink can also be attached to the cold plate 305 for additional cooling capacity but is not depicted in FIG. 3 for illustrative ease. Here, there are one or more fluidic channels within the cold plate 305 that are attached to an inlet 311 on one end and an outlet 312 on the other end. Cold fluid is pumped through a tube or other conduit (not shown) that is coupled to the inlet 311. The fluid runs through the channels within the cold plate 305 and absorbs heat that the cold plate has received from the chip package. The warmed fluid then leaves the outlet 312, is cooled, returned to the cold plate through the inlet 311 and the process repeats.

Here, as with the approach of FIG. 2, the heat pipes that are thermally coupled to the VR FET heat sinks are attached to the outside of the cold plate 305 (again, they can be screwed to the cold plate with a thermal interface material between them). Thus, heat generated by the VR FETs is transferred to the VR FET heatsinks 303 and the chip package cold plate 305 via the heat pipes 306. The heat is then transferred to the fluid while it runs through the cold plate 305 and is removed from the system by the fluid as it exits the outlet 312.

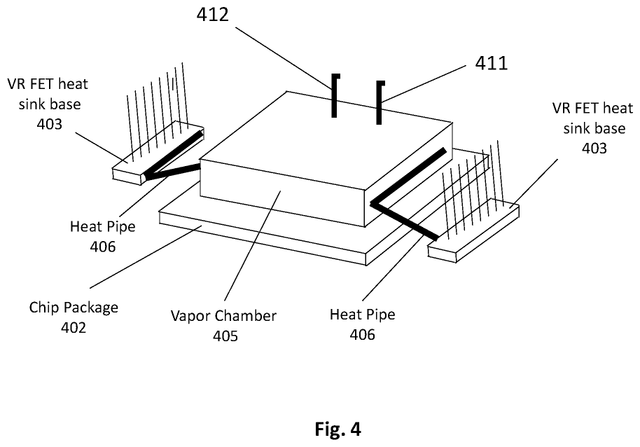

FIG. 4 shows yet another approach that uses two phase cooling rather than traditional liquid cooling. As is known in the art, two phase cooling employs vaporization to further improve cooling capacity. Here, the cold plate is replaced by a vaporization chamber 404. Liquid within chamber absorbs heat from the underlying chip package (and the VR FETs in the arrangement of FIG. 4). When the liquid reaches its boiling point it begins to boil which creates vapor within the chamber. The warmed vapor exits the chamber from the outlet 412 thereby removing heat from the system. Externally, the vapor is condensed back into a liquid and returned to the chamber via inlet 411.

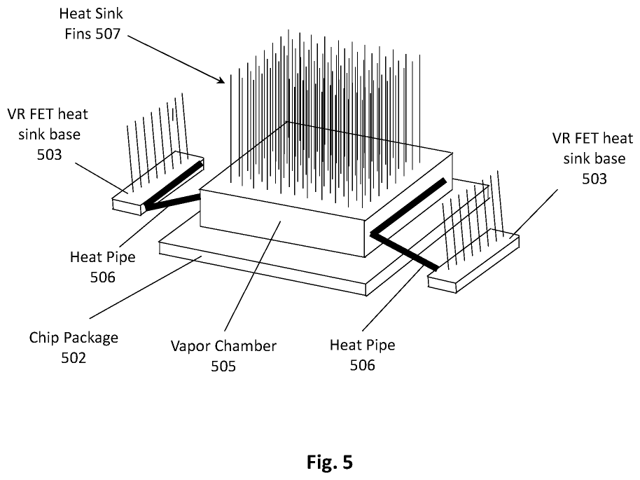

FIG. 5 shows another liquid two phase cooling approach in which the liquid and vapor remains in the chamber 505. That is, the chamber 505 is sealed such that there are no inlets or outlets. In this particular approach there is typically a heat sink that sits on top of the vapor chamber. Vertical tubes from the chamber 305 extend into the heat sink fins 507 so that the vapor within the chamber 505 can expand into the tubes and warm the fins 507. Air flow from the fans then passes through the fins 507 and removes heat from the system, which, in turn, condenses the vapor back into a liquid which falls into the coolant bath in the chamber. In the particular embodiment of FIG. 5, as with the approach of FIG. 4, the heat pipes 506 are attached to the sides of the vapor chamber 505.

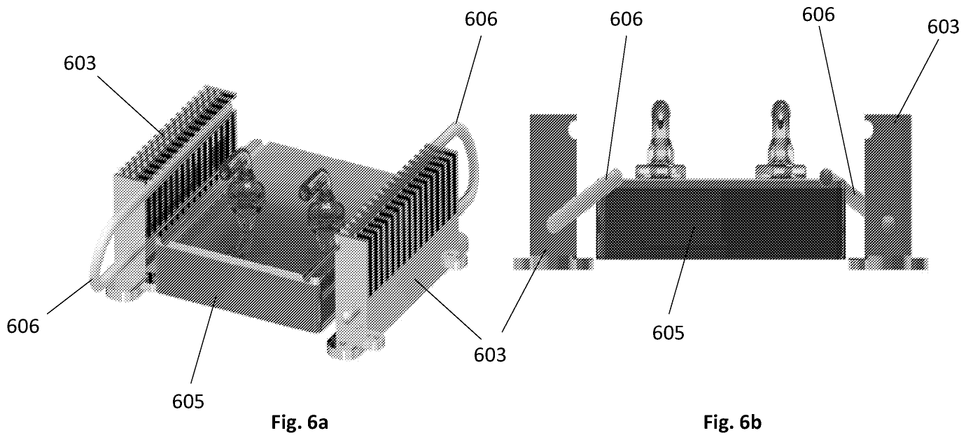

FIGS. 6a and 6b shows an extension to any of the approaches of FIGS. 3, 4 and 5. Here, the approaches of FIGS. 3, 4 and 5, although employing different cooling mechanisms, each have the VR FET heat pipes connected to the outside of the cold plate or vapor chamber (both of which are hereinafter referred to simply as “chamber”). FIGS. 6a and 6b depict an approach where the heat pipes 606 are hinged at the VR FET heat sink 603 to allow easy removal and/or insertion of the chip package and/or its cooling assembly (chamber).

In a first position, depicted in FIG. 6a, the heat pipes 606 are rotated in an upward “stowed” position to allow east access to the chip package and/or its cooling assembly. In a second “deployed” position, depicted in FIG. 6b, the heat pipes 606 are rotated in a downward position so that they make contact with and are thermally coupled to the chamber 605. Thus, in the deployed position (FIG. 6b) the VR FET heat sinks 603 receive thermal cooling assistance from the chamber 605, whereas, in the stowed position (FIG. 6a), they do not. The top of the chamber 605 can have grooves or other shapes to mate with the shape of the heat pipe to increase the surface area of contact between the heat pipes 606 and chamber 605.

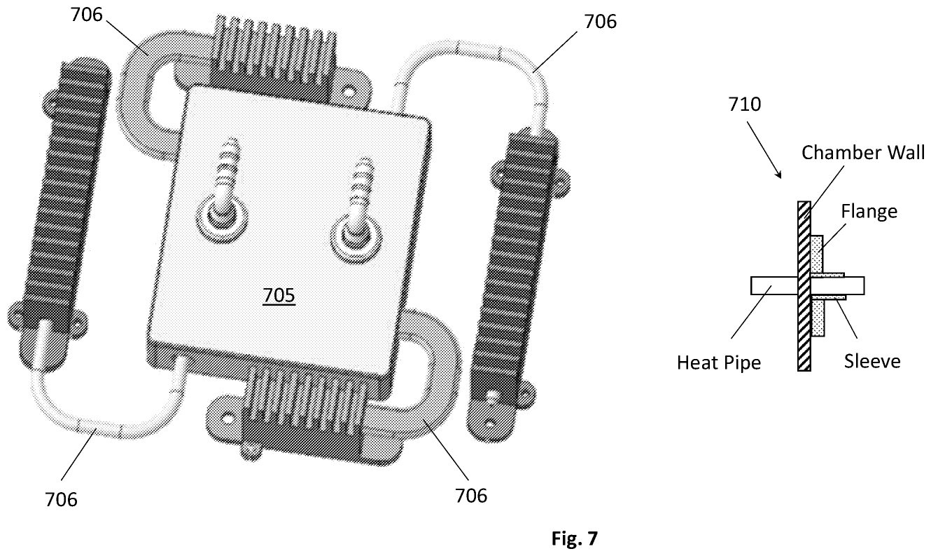

FIG. 7 shows another liquid cooled approach in which the heat pipes 706 run into the chamber 705 and are immersed in the chamber's liquid. The approach of FIG. 7 can be applied to either traditional liquid cooling (e.g., as an improvement to the approach FIG. 3) or two phase immersion cooling (e.g., as an improvement to the approaches of FIGS. 4 and 5). Running the heat pipes 706 directly into the chamber's liquid bath significantly enhances the heat transfer efficiency from the VR FETs. Specifically, there is some thermal inefficiency associated with the heat transfer from the pipes to the outside of the chamber as with the approaches described above with respect to FIGS. 3, 4 and 5.

Specifically, two thermal interfaces are crossed to reach the liquid bath (from the pipe to the chamber wall, and then from the chamber wall to the liquid) which increases the thermal resistance. Additionally, only the surface area of the pipe that makes contact to the chamber is physically involved with the heat transfer process. By contrast, with respect to the approach of FIG. 7, heat is not only transferred directly to the bath from the heat pipe 706, but also, the entire surface area of the portion of the heat pipe 706 that is submerged in the liquid participates in the heat transfer. Note that some heat pipes are cylindrical while other heat pipes are flat.

In the particular embodiment of FIG. 7, holes are cut in the walls of the chamber 705 at the locations where the pipes 706 enter the chamber 705. One or more mechanical elements can be used to affix each heat pipe 706 to the vapor chamber in a manner that prevents leakage of the liquid from the chamber 705. For example, as observed in inset 710, a tight fitting sleeve and flange element can be used whereby the sleeve fits over the pipe and the flange is secured to the chamber wall with screws. A liquid repellant grease, for example, could be coated on the backside of the flange and the inside of the sleeve so that the grease fills any/all spaces between the flange and chamber wall, and, the sleeve and heat pipe.

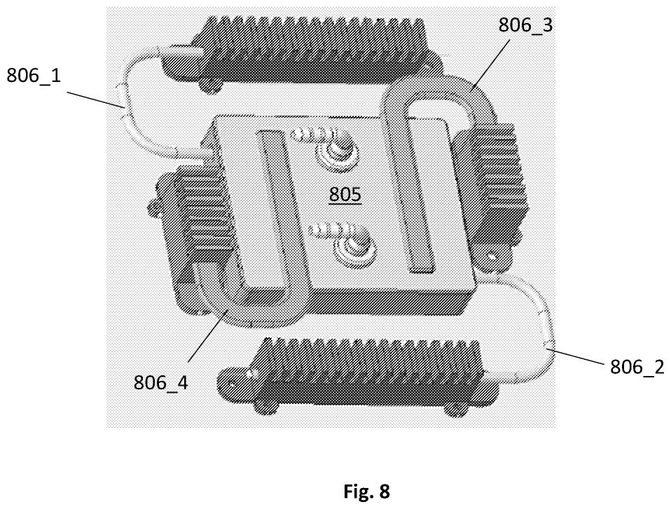

FIG. 8 shows another approach where some heat pipes 806_1, 806_2 enter the chamber 805 and are immersed in the liquid as described above with respect to FIG. 7, whereas, other heat pipes 806_3, 806_4 are mounted to the outside of the chamber 805. As with the approach of FIG. 7, the approach of FIG. 8 can be applied to either traditional liquid cooling or two phase immersion cooling.

As observed in FIG. 8, heat pipes 806_1, 806_2 are routed into the chamber 805 whereas heat pipes 806_3, 806_4 are fixed to the top of the chamber 805. As can be seen, the heat sinks that pipes 806_1, 806_2 are coupled to are larger than the heat sinks that pipes 806_3, 806_4 and therefore receive more heat from their underlying VR FETs. As such, heat pipes 806_1, 806_2 are provided the greater cooling capacity associated with being immersed in the liquid whereas heat pipes 806_3, 806_4 are provided with the lesser cooling capacity of being thermally coupled to the outside of the chamber 805.

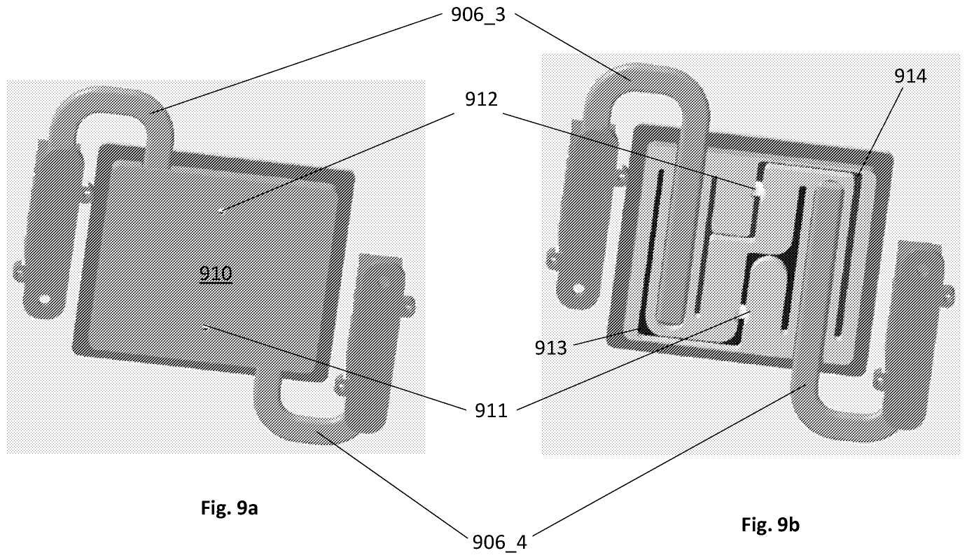

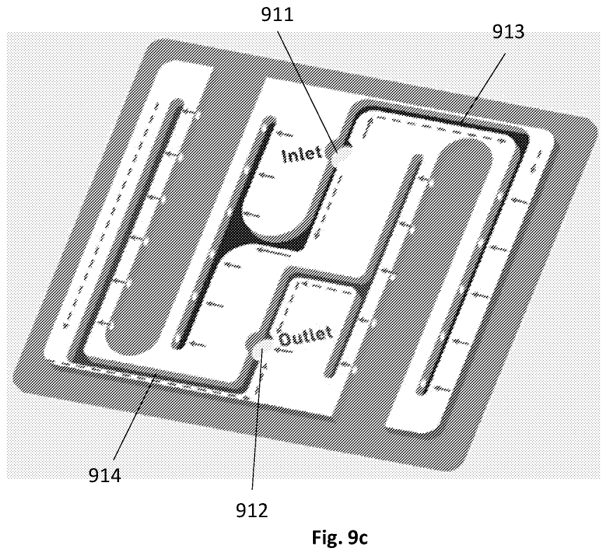

FIGS. 9a and 9b show an improvement to the approach of FIG. 8 in which all four heat pipes receive at least some direct contact with the cooling liquid. Here, the heat pipes 806_3, 806_4 that were mounted to the outside of the chamber in FIG. 8 are instead routed to the inside of the chamber and integrated with the chamber ceiling in an arrangement that causes them to be sprayed with cooled liquid as the cooled liquid enters the chamber.

In the case of traditional liquid cooling, the liquid that comes in contact with heat pipes 906_3, 906_4 exits an outlet with the warmed fluid that exits the chamber. In the case of two phase immersion cooling, liquid that comes in contact with heat pipes 906_3, 906_4 vaporizes and exits the outlet with vapor that exits the chamber. In this case, the inlet corresponds to the liquid return for the two phase immersion cooling system.

FIG. 9a shows an underside view of the ceiling of the chamber. As observed in FIG. 9a, the heat pipes 906_3, 906_4 that are integrated into the ceiling are covered by a plate 910 that corresponds to the ceiling of the chamber. The ceiling/plate has a first hole 911 that is coupled to the inlet so that liquid can enter the chamber. The ceiling/plate has a second hole 912 that is coupled to the outlet so that warmed liquid (in the case of traditional liquid cooling) or vapor (in the case of two phase immersion) can exit the chamber.

FIG. 9b shows the design when the ceiling/plate is removed. As observed in FIG. 9b, the heat pipes 906_3, 906_4 fit into grooves formed on the underside of the top of the unit. The underside of the top of the unit also has channels 913, 914 formed therein. A first channel 913 is coupled to the inlet and therefore receives cooled fluid. The channel 913 extends to one side of the heat pipes so that the heat pipes directly receive the fluid. The fluid receives the heat and warms in response. In the case of traditional liquid cooling, the warmed fluid flows through a second exit channel 914 that is coupled to the outlet and exits the system through the outlet.

In the case of two phase immersion cooling, the vaporized liquid flows through the exit channel 914 and exits the system through the outlet. In either liquid cooled approach (traditional or two-phase immersion), according to one approach, depicted in FIG. 9c, there is some space between the heat pipes and the grooves in the underside of the top of the unit that the pipes are placed within, and, both the first channel 913 and second channel 914 are fluidically coupled to this space (e.g., by holes that run along the sides of the grooves that the heat pipes are fit into).

According to an alternative or combined approach, the outer face of the ceiling/plate (the side of the ceiling/plate 910 that faces the heat pipes as opposed to the side of the ceiling plate 910 that is observed in FIG. 9a and faces the inside of the chamber) acts as a pan that collects warmed or boiling fluid. That is, warmed fluid/vapor from the first channel 913 falls into the pan and then exits the pan through the second channel 914.

In various embodiments, the fluid is “jet impinged” onto the heat pipes from the first channel 913. That is, for example, the aforementioned holes in the first channel 913 that run along the side of the heat pipes have associated sizes, shapes, etc. that, e.g., in conjunction with the fluidic pressure in the first channel, cause the fluid to “jet” from the holes and impinge upon the heat pipes with high velocity, which, in turn enhances the efficiency of the heat removal from the heat pipes.

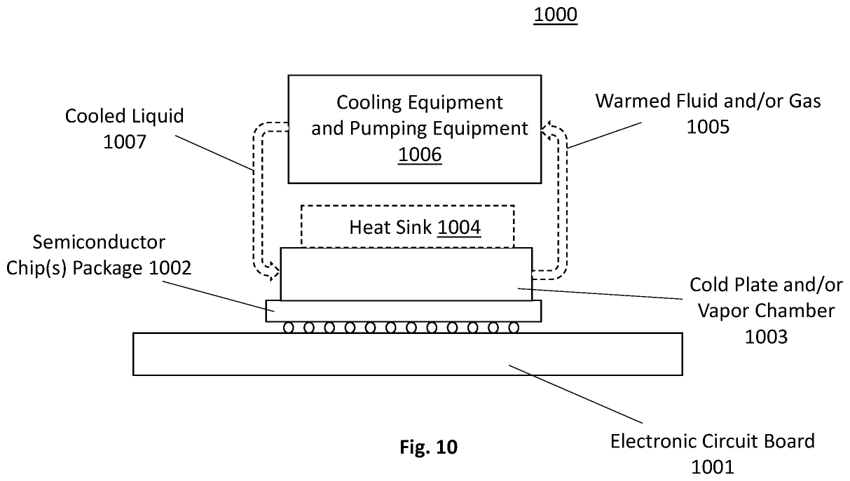

The teachings above can be applied to the cooling apparatus 1000 of FIG. 10. FIG. 10 depicts a general cooling apparatus 1000 whose features can be found in many different kinds of semiconductor chip cooling systems. As observed in FIG. 10, one or more semiconductor chips within a package 1002 are mounted to an electronic circuit board 1001. A cold plate 1003 is thermally coupled with the package 1002 (e.g., by being placed on the package 1002 with a thermally conductive material (“thermal interface material”) between them) so that the cold plate 1003 receives heat generated by the one or more semiconductor chips (the cold plate 1003 can also be referred to as a vapor chamber in the case of two phase cooling systems).

Liquid coolant is within the cold plate 1003. If the system also employs air cooling (optional), a heat sink 1004 can be thermally coupled to the cold plate 1003. Warmed liquid coolant and/or vapor 1005 leaves the cold plate 1003 to be cooled by one or more items of cooling equipment (e.g., heat exchanger(s), radiator(s), condenser(s), refrigeration unit(s), etc.) and pumped by one or more items of pumping equipment (e.g., dynamic (e.g., centrifugal), positive displacement (e.g., rotary, reciprocating, etc.)) 1006. Cooled liquid 1007 then enters the cold plate 1003 and the process repeats.

With respect to the cooling equipment and pumping equipment 1006, cooling activity can precede pumping activity, pumping activity can precede cooling activity, or multiple stages of one or both of pumping and cooling can be intermixed (e.g., in order of flow: a first cooling stage, a first pumping stage, a second cooling stage, a second pumping stage, etc.) and/or other combinations of cooling activity and pumping activity can take place.

Moreover, the intake of any equipment of the cooling equipment and pumping equipment 1006 can be supplied by the cold plate of one semiconductor chip package or the respective cold plate(s) of multiple semiconductor chip packages.

In the case of the later (intake received from cold plate(s) of multiple semiconductor chip packages), the semiconductor chip packages can be components on a same electronic circuit board or multiple electronic circuit boards. In the case of the later (multiple electronic circuit boards), the multiple electronic circuit boards can be components of a same electronic system (e.g., different boards in a same server computer) or different electronic systems (e.g., electronic circuit boards from different server computers). In essence, the general depiction of FIG. 10 describes compact cooling systems (e.g., a cooling system contained within a single electronic system), expansive cooling systems (e.g., cooling systems that cool the components of any of a rack, multiple racks, a data center, etc.) and cooling systems in between.

FIG. 10 also describes immersion cooling systems where it is understood that the warmed fluid and/or vapor flow 1005 is from the immersion bath chamber (not shown for illustrative ease) and the cooled fluid flow is 1007 is into the immersion bath chamber.

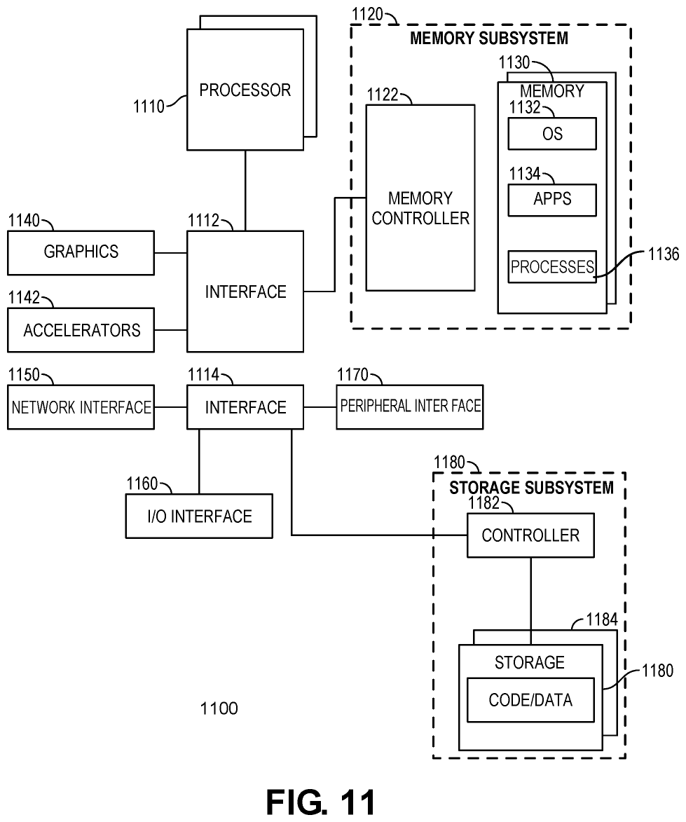

The following discussion concerning FIGS. 11, 12 and 13 are directed to systems, data centers and rack implementations, generally. It is pertinent to point out that any electronic circuit board of any of the systems, data centers and rack implementations described below can include heat pipes to thermally couple the chamber of a chip package cooling assembly to heat sinks that cool semiconductor chips or devices outside the chip package.

FIG. 11 depicts an example system. System 1100 includes processor 1110, which provides processing, operation management, and execution of instructions for system 1100. Processor 1110 can include any type of microprocessor, central processing unit (CPU), graphics processing unit (GPU), processing core, or other processing hardware to provide processing for system 1100, or a combination of processors. Processor 1110 controls the overall operation of system 1100, and can be or include, one or more programmable general-purpose or special-purpose microprocessors, digital signal processors (DSPs), programmable controllers, application specific integrated circuits (ASICs), programmable logic devices (PLDs), or the like, or a combination of such devices.

Certain systems also perform networking functions (e.g., packet header processing functions such as, to name a few, next nodal hop lookup, priority/flow lookup with corresponding queue entry, etc.), as a side function, or, as a point of emphasis (e.g., a networking switch or router). Such systems can include one or more network processors to perform such networking functions (e.g., in a pipelined fashion or otherwise).

In one example, system 1100 includes interface 1112 coupled to processor 1110, which can represent a higher speed interface or a high throughput interface for system components that needs higher bandwidth connections, such as memory subsystem 1120 or graphics interface components 1140, or accelerators 1142. Interface 1112 represents an interface circuit, which can be a standalone component or integrated onto a processor die. Where present, graphics interface 1140 interfaces to graphics components for providing a visual display to a user of system 1100. In one example, graphics interface 1140 can drive a high definition (HD) display that provides an output to a user. High definition can refer to a display having a pixel density of approximately 100 PPI (pixels per inch) or greater and can include formats such as full HD (e.g., 1080p), retina displays, 4K (ultra-high definition or UHD), or others. In one example, the display can include a touchscreen display. In one example, graphics interface 1140 generates a display based on data stored in memory 1130 or based on operations executed by processor 1110 or both. In one example, graphics interface 1140 generates a display based on data stored in memory 1130 or based on operations executed by processor 1110 or both.

Accelerators 1142 can be a fixed function offload engine that can be accessed or used by a processor 1110. For example, an accelerator among accelerators 1142 can provide compression (DC) capability, cryptography services such as public key encryption (PKE), cipher, hash/authentication capabilities, decryption, or other capabilities or services. In some embodiments, in addition or alternatively, an accelerator among accelerators 1142 provides field select controller capabilities as described herein. In some cases, accelerators 1142 can be integrated into a CPU socket (e.g., a connector to a motherboard or circuit board that includes a CPU and provides an electrical interface with the CPU). For example, accelerators 1142 can include a single or multi-core processor, graphics processing unit, logical execution unit single or multi-level cache, functional units usable to independently execute programs or threads, application specific integrated circuits (ASICs), neural network processors (NNPs), “X” processing units (XPUs), programmable control logic, and programmable processing elements such as field programmable gate arrays (FPGAs). Accelerators 1142 can provide multiple neural networks, processor cores, or graphics processing units can be made available for use by artificial intelligence (AI) or machine learning (ML) models. For example, the AI model can use or include any or a combination of: a reinforcement learning scheme, Q-learning scheme, deep-Q learning, or Asynchronous Advantage Actor-Critic (A3C), combinatorial neural network, recurrent combinatorial neural network, or other AI or ML model. Multiple neural networks, processor cores, or graphics processing units can be made available for use by AI or ML models.

Memory subsystem 1120 represents the main memory of system 1100 and provides storage for code to be executed by processor 1110, or data values to be used in executing a routine. Memory subsystem 1120 can include one or more memory devices 1130 such as read-only memory (ROM), flash memory, volatile memory, or a combination of such devices. Memory 1130 stores and hosts, among other things, operating system (OS) 1132 to provide a software platform for execution of instructions in system 1100. Additionally, applications 1134 can execute on the software platform of OS 1132 from memory 1130. Applications 1134 represent programs that have their own operational logic to perform execution of one or more functions. Processes 1136 represent agents or routines that provide auxiliary functions to OS 1132 or one or more applications 1134 or a combination. OS 1132, applications 1134, and processes 1136 provide software logic to provide functions for system 1100. In one example, memory subsystem 1120 includes memory controller 1122, which is a memory controller to generate and issue commands to memory 1130. It will be understood that memory controller 1122 could be a physical part of processor 1110 or a physical part of interface 1112. For example, memory controller 1122 can be an integrated memory controller, integrated onto a circuit with processor 1110. In some examples, a system on chip (SOC or SoC) combines into one SoC package one or more of: processors, graphics, memory, memory controller, and Input/Output (I/O) control logic.

A volatile memory is memory whose state (and therefore the data stored in it) is indeterminate if power is interrupted to the device. Dynamic volatile memory requires refreshing the data stored in the device to maintain state. One example of dynamic volatile memory incudes DRAM (Dynamic Random Access Memory), or some variant such as Synchronous DRAM (SDRAM). A memory subsystem as described herein may be compatible with a number of memory technologies, such as DDR3 (Double Data Rate version 3, original release by JEDEC (Joint Electronic Device Engineering Council) on Jun. 27, 2007). DDR4 (DDR version 4, initial specification published in September 2012 by JEDEC), DDR4E (DDR version 4), LPDDR3 (Low Power DDR version3, JESD209-3B, August 2013 by JEDEC), LPDDR4) LPDDR version 4, JESD209-4, originally published by JEDEC in August 2014), WIO2 (Wide Input/Output version 2, JESD229-2 originally published by JEDEC in August 2014, HBM (High Bandwidth Memory), JESD235, originally published by JEDEC in October 2013, LPDDR5, HBM2 (HBM version 2), or others or combinations of memory technologies, and technologies based on derivatives or extensions of such specifications.

In various implementations, memory resources can be “pooled”. For example, the memory resources of memory modules installed on multiple cards, blades, systems, etc. (e.g., that are inserted into one or more racks) are made available as additional main memory capacity to CPUs and/or servers that need and/or request it. In such implementations, the primary purpose of the cards/blades/systems is to provide such additional main memory capacity. The cards/blades/systems are reachable to the CPUs/servers that use the memory resources through some kind of network infrastructure such as CXL, CAPI, etc.

While not specifically illustrated, it will be understood that system 1100 can include one or more buses or bus systems between devices, such as a memory bus, a graphics bus, interface buses, or others. Buses or other signal lines can communicatively or electrically couple components together, or both communicatively and electrically couple the components. Buses can include physical communication lines, point-to-point connections, bridges, adapters, controllers, or other circuitry or a combination. Buses can include, for example, one or more of a system bus, a Peripheral Component Interconnect express (PCIe) bus, a HyperTransport or industry standard architecture (ISA) bus, a small computer system interface (SCSI) bus, Remote Direct Memory Access (RDMA), Internet Small Computer Systems Interface (iSCSI), NVM express (NVMe), Coherent Accelerator Interface (CXL), Coherent Accelerator Processor Interface (CAPI), Cache Coherent Interconnect for Accelerators (CCIX), Open Coherent Accelerator Processor (Open CAPI) or other specification developed by the Gen-z consortium, a universal serial bus (USB), or an Institute of Electrical and Electronics Engineers (IEEE) standard 1394 bus.

In one example, system 1100 includes interface 1114, which can be coupled to interface 1112. In one example, interface 1114 represents an interface circuit, which can include standalone components and integrated circuitry. In one example, multiple user interface components or peripheral components, or both, couple to interface 1114. Network interface 1150 provides system 1100 the ability to communicate with remote devices (e.g., servers or other computing devices) over one or more networks. Network interface 1150 can include an Ethernet adapter, wireless interconnection components, cellular network interconnection components, USB (universal serial bus), or other wired or wireless standards-based or proprietary interfaces. Network interface 1150 can transmit data to a remote device, which can include sending data stored in memory. Network interface 1150 can receive data from a remote device, which can include storing received data into memory. Various embodiments can be used in connection with network interface 1150, processor 1110, and memory subsystem 1120.

In one example, system 1100 includes one or more input/output (I/O) interface(s) 1160. I/O interface 1160 can include one or more interface components through which a user interacts with system 1100 (e.g., audio, alphanumeric, tactile/touch, or other interfacing). Peripheral interface 1170 can include any hardware interface not specifically mentioned above. Peripherals refer generally to devices that connect dependently to system 1100. A dependent connection is one where system 1100 provides the software platform or hardware platform or both on which operation executes, and with which a user interacts.

In one example, system 1100 includes storage subsystem 1180 to store data in a nonvolatile manner. In one example, in certain system implementations, at least certain components of storage 1180 can overlap with components of memory subsystem 1120. Storage subsystem 1180 includes storage device(s) 1184, which can be or include any conventional medium for storing large amounts of data in a nonvolatile manner, such as one or more magnetic, solid state, or optical based disks, or a combination. Storage 1184 holds code or instructions and data in a persistent state (e.g., the value is retained despite interruption of power to system 1100). Storage 1184 can be generically considered to be a “memory,” although memory 1130 is typically the executing or operating memory to provide instructions to processor 1110. Whereas storage 1184 is nonvolatile, memory 1130 can include volatile memory (e.g., the value or state of the data is indeterminate if power is interrupted to system 1100). In one example, storage subsystem 1180 includes controller 1182 to interface with storage 1184. In one example controller 1182 is a physical part of interface 1114 or processor 1110 or can include circuits or logic in both processor 1110 and interface 1114.

A non-volatile memory (NVM) device is a memory whose state is determinate even if power is interrupted to the device. In one embodiment, the NVM device can comprise a block addressable memory device, such as NAND technologies, or more specifically, multi-threshold level NAND flash memory (for example, Single-Level Cell (“SLC”), Multi-Level Cell (“MLC”), Quad-Level Cell (“QLC”), Tri-Level Cell (“TLC”), or some other NAND). A NVM device can also comprise a byte-addressable write-in-place three dimensional cross point memory device, or other byte addressable write-in-place NVM device (also referred to as persistent memory), such as single or multi-level Phase Change Memory (PCM) or phase change memory with a switch (PCMS), NVM devices that use chalcogenide phase change material (for example, chalcogenide glass), resistive memory including metal oxide base, oxygen vacancy base and Conductive Bridge Random Access Memory (CB-RAM), nanowire memory, ferroelectric random access memory (FeRAM, FRAM), magneto resistive random access memory (MRAM) that incorporates memristor technology, spin transfer torque (STT)-MRAM, a spintronic magnetic junction memory based device, a magnetic tunneling junction (MTJ) based device, a DW (Domain Wall) and SOT (Spin Orbit Transfer) based device, a thyristor based memory device, or a combination of any of the above, or other memory.

A power source (not depicted) provides power to the components of system 1100. More specifically, power source typically interfaces to one or multiple power supplies in system 1100 to provide power to the components of system 1100. In one example, the power supply includes an AC to DC (alternating current to direct current) adapter to plug into a wall outlet. Such AC power can be renewable energy (e.g., solar power) power source. In one example, power source includes a DC power source, such as an external AC to DC converter. In one example, power source or power supply includes wireless charging hardware to charge via proximity to a charging field. In one example, power source can include an internal battery, alternating current supply, motion-based power supply, solar power supply, or fuel cell source.

In an example, system 1100 can be implemented as a disaggregated computing system. For example, the system 1100 can be implemented with interconnected compute sleds of processors, memories, storages, network interfaces, and other components. High speed interconnects can be used such as PCIe, Ethernet, or optical interconnects (or a combination thereof). For example, the sleds can be designed according to any specifications promulgated by the Open Compute Project (OCP) or other disaggregated computing effort, which strives to modularize main architectural computer components into rack-pluggable components (e.g., a rack pluggable processing component, a rack pluggable memory component, a rack pluggable storage component, a rack pluggable accelerator component, etc.).

Although a computer is largely described by the above discussion of FIG. 11, other types of systems to which the above described invention can be applied and are also partially or wholly described by FIG. 11 are communication systems such as routers, switches and base stations.

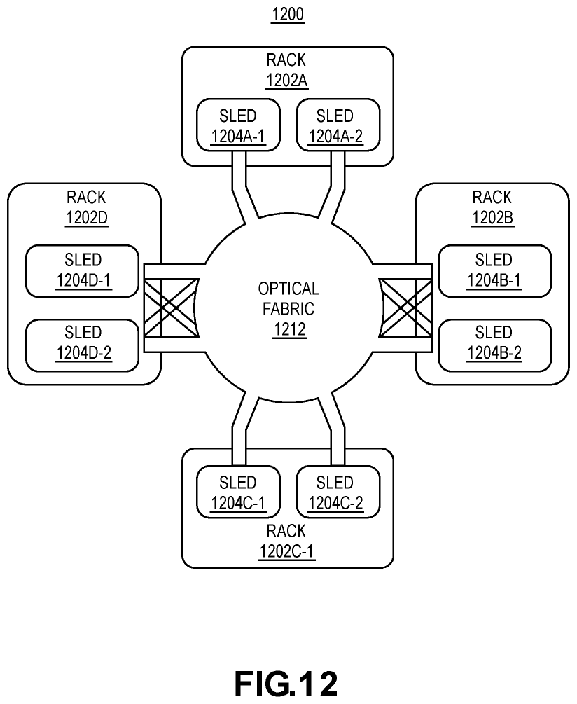

FIG. 12 depicts an example of a data center. Various embodiments can be used in or with the data center of FIG. 12. As shown in FIG. 12, data center 1200 may include an optical fabric 1212. Optical fabric 1212 may generally include a combination of optical signaling media (such as optical cabling) and optical switching infrastructure via which any particular sled in data center 1200 can send signals to (and receive signals from) the other sleds in data center 1200. However, optical, wireless, and/or electrical signals can be transmitted using fabric 1212. The signaling connectivity that optical fabric 1212 provides to any given sled may include connectivity both to other sleds in a same rack and sleds in other racks.

Data center 1200 includes four racks 1202A to 1202D and racks 1202A to 1202D house respective pairs of sleds 1204A-1 and 1204A-2, 1204B-1 and 1204B-2, 1204C-1 and 1204C-2, and 1204D-1 and 1204D-2. Thus, in this example, data center 1200 includes a total of eight sleds. Optical fabric 1212 can provide sled signaling connectivity with one or more of the seven other sleds. For example, via optical fabric 1212, sled 1204A-1 in rack 1202A may possess signaling connectivity with sled 1204A-2 in rack 1202A, as well as the six other sleds 1204B-1, 1204B-2, 1204C-1, 1204C-2, 1204D-1, and 1204D-2 that are distributed among the other racks 1202B, 1202C, and 1202D of data center 1200. The embodiments are not limited to this example. For example, fabric 1212 can provide optical and/or electrical signaling.

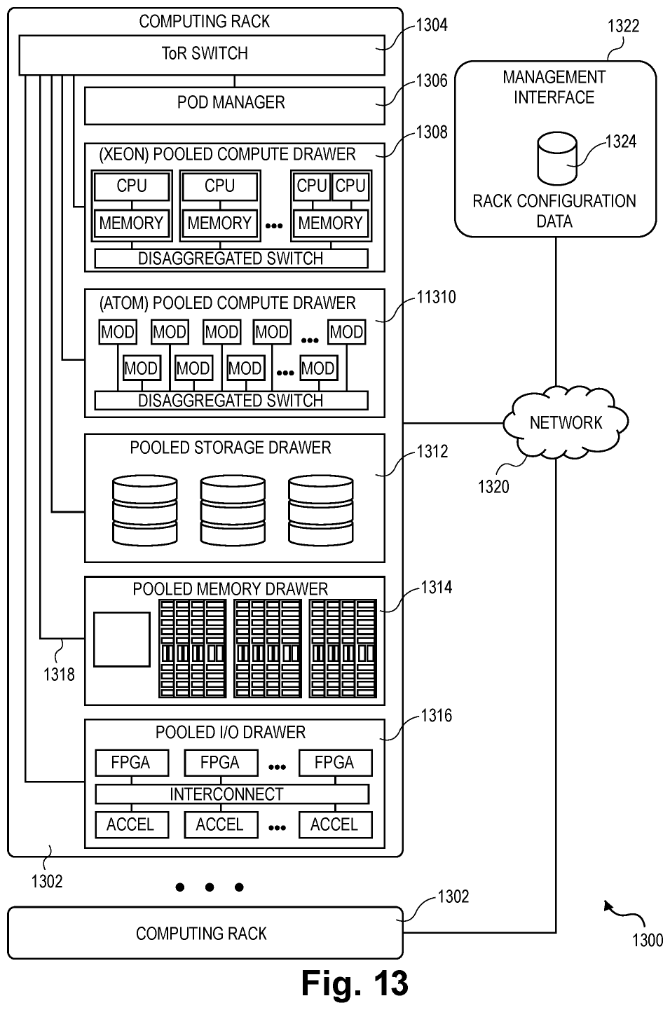

FIG. 13 depicts an environment 1300 that includes multiple computing racks 1302, each including a Top of Rack (ToR) switch 1304, a pod manager 1306, and a plurality of pooled system drawers. Generally, the pooled system drawers may include pooled compute drawers and pooled storage drawers to, e.g., effect a disaggregated computing system. Optionally, the pooled system drawers may also include pooled memory drawers and pooled Input/Output (I/O) drawers. In the illustrated embodiment the pooled system drawers include an INTEL® XEON® pooled computer drawer 1308, and INTEL® ATOM™ pooled compute drawer 1310, a pooled storage drawer 1312, a pooled memory drawer 1314, and a pooled I/O drawer 1316. Each of the pooled system drawers is connected to TOR switch 1304 via a high-speed link 1318, such as a 40 Gigabit/second (Gb/s) or 100 Gb/s Ethernet link or an 100+Gb/s Silicon Photonics (SiPh) optical link. In one embodiment high-speed link 1318 comprises an 600 Gb/s SiPh optical link.

Again, the drawers can be designed according to any specifications promulgated by the Open Compute Project (OCP) or other disaggregated computing effort, which strives to modularize main architectural computer components into rack-pluggable components (e.g., a rack pluggable processing component, a rack pluggable memory component, a rack pluggable storage component, a rack pluggable accelerator component, etc.).

Multiple of the computing racks 1300 may be interconnected via their TOR switches 1304 (e.g., to a pod-level switch or data center switch), as illustrated by connections to a network 1320. In some embodiments, groups of computing racks 1302 are managed as separate pods via pod manager(s) 1306. In one embodiment, a single pod manager is used to manage all of the racks in the pod. Alternatively, distributed pod managers may be used for pod management operations. RSD environment 1300 further includes a management interface 1322 that is used to manage various aspects of the RSD environment. This includes managing rack configuration, with corresponding parameters stored as rack configuration data 1324.

Any of the systems, data centers or racks discussed above, apart from being integrated in a typical data center, can also be implemented in other environments such as within a bay station, or other micro-data center, e.g., at the edge of a network.

Embodiments herein may be implemented in various types of computing, smart phones, tablets, personal computers, and networking equipment, such as switches, routers, racks, and blade servers such as those employed in a data center and/or server farm environment. The servers used in data centers and server farms comprise arrayed server configurations such as rack-based servers or blade servers. These servers are interconnected in communication via various network provisions, such as partitioning sets of servers into Local Area Networks (LANs) with appropriate switching and routing facilities between the LANs to form a private Intranet. For example, cloud hosting facilities may typically employ large data centers with a multitude of servers. A blade comprises a separate computing platform that is configured to perform server-type functions, that is, a “server on a card.” Accordingly, each blade includes components common to conventional servers, including a main printed circuit board (main board) providing internal wiring (e.g., buses) for coupling appropriate integrated circuits (ICs) and other components mounted to the board.

Various examples may be implemented using hardware elements, software elements, or a combination of both. In some examples, hardware elements may include devices, components, processors, microprocessors, circuits, circuit elements (e.g., transistors, resistors, capacitors, inductors, and so forth), integrated circuits, ASICs, PLDs, DSPs, FPGAs, memory units, logic gates, registers, semiconductor device, chips, microchips, chip sets, and so forth. In some examples, software elements may include software components, programs, applications, computer programs, application programs, system programs, machine programs, operating system software, middleware, firmware, software modules, routines, subroutines, functions, methods, procedures, software interfaces, APIs, instruction sets, computing code, computer code, code segments, computer code segments, words, values, symbols, or any combination thereof. Determining whether an example is implemented using hardware elements and/or software elements may vary in accordance with any number of factors, such as desired computational rate, power levels, heat tolerances, processing cycle budget, input data rates, output data rates, memory resources, data bus speeds and other design or performance constraints, as desired for a given implementation.

Some examples may be implemented using or as an article of manufacture or at least one computer-readable medium. A computer-readable medium may include a non-transitory storage medium to store logic. In some examples, the non-transitory storage medium may include one or more types of computer-readable storage media capable of storing electronic data, including volatile memory or non-volatile memory, removable or non-removable memory, erasable or non-erasable memory, writeable or re-writeable memory, and so forth. In some examples, the logic may include various software elements, such as software components, programs, applications, computer programs, application programs, system programs, machine programs, operating system software, middleware, firmware, software modules, routines, subroutines, functions, methods, procedures, software interfaces, API, instruction sets, computing code, computer code, code segments, computer code segments, words, values, symbols, or any combination thereof.

According to some examples, a computer-readable medium may include a non-transitory storage medium to store or maintain instructions that when executed by a machine, computing device or system, cause the machine, computing device or system to perform methods and/or operations in accordance with the described examples. The instructions may include any suitable type of code, such as source code, compiled code, interpreted code, executable code, static code, dynamic code, and the like. The instructions may be implemented according to a predefined computer language, manner or syntax, for instructing a machine, computing device or system to perform a certain function. The instructions may be implemented using any suitable high-level, low-level, object-oriented, visual, compiled and/or interpreted programming language.

To the extent any of the teachings above can be embodied in a semiconductor chip, a description of a circuit design of the semiconductor chip for eventual targeting toward a semiconductor manufacturing process can take the form of various formats such as a (e.g., VHDL or Verilog) register transfer level (RTL) circuit description, a gate level circuit description, a transistor level circuit description or mask description or various combinations thereof. Such circuit descriptions, sometimes referred to as “IP Cores”, are commonly embodied on one or more computer readable storage media (such as one or more CD-ROMs or other type of storage technology) and provided to and/or otherwise processed by and/or for a circuit design synthesis tool and/or mask generation tool. Such circuit descriptions may also be embedded with program code to be processed by a computer that implements the circuit design synthesis tool and/or mask generation tool.

The appearances of the phrase “one example” or “an example” are not necessarily all referring to the same example or embodiment. Any aspect described herein can be combined with any other aspect or similar aspect described herein, regardless of whether the aspects are described with respect to the same figure or element. Division, omission or inclusion of block functions depicted in the accompanying figures does not infer that the hardware components, circuits, software and/or elements for implementing these functions would necessarily be divided, omitted, or included in embodiments.

Some examples may be described using the expression “coupled” and “connected” along with their derivatives. These terms are not necessarily intended as synonyms for each other. For example, descriptions using the terms “connected” and/or “coupled” may indicate that two or more elements are in direct physical or electrical contact with each other. The term “coupled,” however, may also mean that two or more elements are not in direct contact with each other, but yet still co-operate or interact with each other.

The terms “first,” “second,” and the like, herein do not denote any order, quantity, or importance, but rather are used to distinguish one element from another. The terms “a” and “an” herein do not denote a limitation of quantity, but rather denote the presence of at least one of the referenced items. The term “asserted” used herein with reference to a signal denote a state of the signal, in which the signal is active, and which can be achieved by applying any logic level either logic 0 or logic 1 to the signal. The terms “follow” or “after” can refer to immediately following or following after some other event or events. Other sequences may also be performed according to alternative embodiments. Furthermore, additional sequences may be added or removed depending on the particular applications. Any combination of changes can be used and one of ordinary skill in the art with the benefit of this disclosure would understand the many variations, modifications, and alternative embodiments thereof.

Disjunctive language such as the phrase “at least one of X, Y, or Z,” unless specifically stated otherwise, is otherwise understood within the context as used in general to present that an item, term, etc., may be either X, Y, or Z, or any combination thereof (e.g., X, Y, and/or Z). Thus, such disjunctive language is not generally intended to, and should not, imply that certain embodiments require at least one of X, at least one of Y, or at least one of Z to each be present. Additionally, conjunctive language such as the phrase “at least one of X, Y, and Z,” unless specifically stated otherwise, should also be understood to mean X, Y, Z, or any combination thereof, including “X, Y, and/or Z.”

1.-20. (canceled)

21. An apparatus, comprising:
a chip package cooling assembly chamber having one or more features to receive one or more heat pipes that receive heat generated by one or more semiconductor devices that reside outside the chip package.

22. The apparatus of claim 21 wherein the chip package cooling assembly chamber comprises channels in which the coolant fluid is to flow to receive the heat.

23. The apparatus of claim 21 wherein the chip package cooling assembly chamber comprises an outlet in which vapor is to be emitted to remove the heat from the chamber.

24. The apparatus of claim 21 wherein, to remove the heat from the chamber, vapor is condensed within channels within heat sink fins that are thermally coupled to the chamber.

25. The apparatus of claim 21 wherein at least one of the one or more heat pipes is to transfer the heat to an external surface of the chamber.

26. The apparatus of claim 21 wherein at least one of the one or more heat pipes is to transfer the heat to a bath of coolant liquid within the chamber.

27. The apparatus of claim 26 wherein at least one other of the one or more heat pipes is to transfer the heat to an external surface of the chamber.

28. The apparatus of claim 21 wherein at least one of the one or more heat pipes is to be jet impinged with liquid coolant after the liquid coolant has been received by an inlet of the chamber.

29. The apparatus of claim 28 wherein the chamber comprises channels behind an inner surface of the chamber to transport the liquid coolant.

30. A data center, comprising:
a plurality of systems plugged into racks, the plurality of systems communicatively coupled to one another via a network
a printed circuit board of one of the systems comprising a chip package having a cooling assembly, the cooling assembly comprising a chamber, the chamber thermally coupled to a heat pipe, the heat pipe thermally coupled to a heat sink, the heat sink thermally coupled to an electronic device that is mounted to the printed circuit board and outside the chip package; and,
cooling and pumping equipment fluidically coupled to the chamber, the cooling and pumping equipment to receive warmed fluid and/or vapor from the chamber and return cooled fluid to the chamber.

31. The data center of claim 30 wherein the heat pipe is rotatable into a position that removes the heat pipe from being thermally coupled to the chamber.

32. The data center of claim 30 wherein the chip package cooling assembly chamber comprises channels in which the fluid is to flow to receive heat from the electronic device.

33. The data center of claim 30 wherein the chip package cooling assembly chamber comprises an outlet in which vapor is emitted to remove heat from the electronic device from the chamber.

34. The data center of claim 30 wherein the heat pipe transfers heat from the electronic device to an external surface of the chamber.

35. The data center of claim 30 wherein the heat pipe transfers heat from the electronic device to a bath of the fluid within the chamber.

36. The data center of claim 35 wherein a second heat pipe that is thermally coupled to the chamber and a second electronic device transfers heat from the second electronic device to an external surface of the chamber.

37. The data center of claim 30 wherein the heat pipe is jet impinged with the cooled fluid after the cooled fluid has been received by an inlet of the chamber.

38. The data center of claim 37 wherein the chamber comprises channels behind an inner surface of the chamber to transport the fluid.

39. An apparatus, comprising:
a heat sink base having one or more features to receive on an outer surface of the heat sink base one or more heat pipes that receive heat generated by one or more semiconductor devices that reside outside a chip package that the heat sink is to be mounted on.

40. The apparatus of claim 39 wherein the one or more heat pipes are to rotationally engage with the heat sink base.
